(19) United States
(12) Patent Application Publication
(10) Pub. No.: US 2015/0059467 A1
(43) Pub. Date: Mar. 5, 2015

(54) OSCILLATOR CIRCUIT

(71) Applicant: DENSO CORPORATION, Kariya-city (JP)

(72) Inventor: Takashi Enomoto, Anjo-city (JP)

(21) Appl. No.: 14/311,694

(22) Filed: Jun. 23, 2014

(30) Foreign Application Priority Data
Aug. 30, 2013 (JP) 2013-179681

(51) Int. Cl. H03L 1/02; G01F 1/696

(52) U.S. Cl. CPC H03L 1/02; G01F 1/696
USPC 73/204.25; 331/66

(57) ABSTRACT

An oscillator circuit includes a resistor configured to control an oscillating frequency. The resistor includes a positive temperature coefficient resistor and a negative temperature coefficient resistor. The positive temperature coefficient resistor has a resistance, which increases in response to increase in temperature. The negative temperature coefficient resistor has a resistance, which decreases in response to increase in temperature.

### CROSS REFERENCE TO RELATED APPLICATION

This application is based on reference Japanese Patent Application No. 2013-179681 filed on Aug. 30, 2013, the disclosure of which is incorporated herein by reference.

### TECHNICAL FIELD

The present disclosure relates to an oscillator circuit including a resistor, which is configured to control an oscillating frequency. The present disclosure may relate to an oscillator circuit employable in a sensor device, such as an airflow meter.

### BACKGROUND

For example, Patent Document 1 discloses a sensor device employing an oscillator circuit including a resistor, which controls an oscillating frequency. The sensor device may be an airflow meter. The sensor device disclosed in Patent document 1 implements A/D conversion on a sensor signal, causes a digital processing unit to correct the ND-converted sensor signal, and implements D/A conversion on the corrected signal. The sensor device includes an oscillator circuit for producing an operation signal for the ND conversion, the computation unit, and the D/A conversion.

The oscillator circuit has a temperature characteristic. Specifically, as shown by a solid line a in FIG. 6, an oscillating frequency changes in response to change in temperature. Therefore, when an environmental temperature of the oscillator circuit changes, the temperature characteristic of the oscillator circuit may cause an error in an operation accuracy of ND conversion and/or D/A conversion. That is, an oscillating frequency of the oscillator circuit may change in response to change in temperature. Consequently, an error may occur in an output signal of the sensor device.

(Patent Document 1)

Publication of unexamined Japanese patent application No. 2003-166865

### SUMMARY

It is an object of the present disclosure to produce an oscillator circuit configured to restrict a temperature dependency on an oscillating frequency.

According to an aspect of the present disclosure, an oscillator circuit comprises a resistor configured to control an oscillating frequency. The resistor includes a positive temperature coefficient resistor and a negative temperature coefficient resistor. The positive temperature coefficient resistor has a resistance, which increases in response to increase in temperature. The negative temperature coefficient resistor has a resistance, which decreases in response to increase in temperature.

### BRIEF DESCRIPTION OF THE DRAWINGS

The above and other objects, features and advantages of the present invention will become more apparent from the following detailed description made with reference to the accompanying drawings. In the drawings:

FIG. 1 is a sectional view showing an airflow meter;

FIG. 2 is a diagram showing a sensor circuit of the airflow meter;

FIG. 3A is a diagram showing a CR oscillator circuit, FIG. 3B is a diagram showing a multi-vibrator oscillator circuit, and FIG. 3C is a diagram showing a ring oscillator circuit;

FIG. 4A is a top view showing a connection state among multiple semiconductor resistor elements and multiple contact resistor elements, and FIG. 4B is a side view showing a connection state among multiple semiconductor resistor elements and multiple contact resistor elements;

FIG. 5 is a graph showing a resistance relative to change in temperature; and

FIG. 6 is a graph showing an oscillation frequency relative to change in temperature.

### DETAILED DESCRIPTION

As follows, embodiment(s) of the present disclosure will be described in detail with reference to drawings.

### First Embodiment

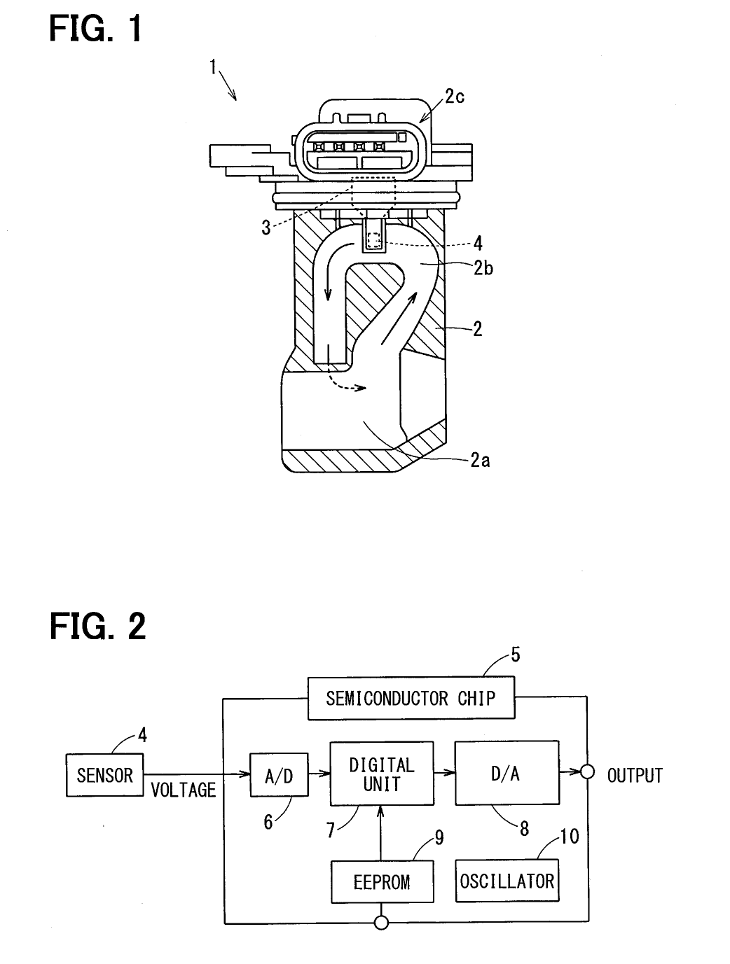

A first embodiment will be described with reference to FIGS. 1 to 6. The first embodiment relates to an airflow meter 1 to which a configuration according to the present disclosure is applied. The airflow meter 1 is one example of a sensor device. The airflow meter 1 is equipped to an air intake duct, which guides intake air to an internal combustion engine for moving a vehicle. The air intake duct is, for example, an air cleaner outlet duct, an intake pipe on the downstream side of an air cleaner, and/or the like.

The airflow meter 1 includes a resin housing 2, a sensor assembly 3, and a thermistor (not shown). The resin housing 2 is formed of resin and attached to the air intake duct. The resin housing 2 is one example of a passage formation member. The sensor assembly 3 is equipped in the resin housing 2 for measuring an amount of intake air flow. The thermistor is equipped to an outside of the resin housing 2 for measuring an amount of intake air flow. The airflow meter 1 may not include the thermistor for measuring an amount of intake air flow.

The resin housing 2 is a secondary resin-mold product. The resin housing 2 may have, for example, a bypass passage 2a and a sub-bypass passage 2b therein. The bypass passage 2a enables a part of intake air, which passes through the air intake duct, to flows therethrough. The sub-bypass passage 2b enables a part of intake air, which passes through the bypass passage 2a, to bypass the bypass passage 2a and to pass through the sub-bypass passage 2b. The configuration of the resin housing 2 is not limited to the present example.

The sensor assembly 3 includes a sensor portion 4 and a semiconductor chip 5. The sensor portion 4 implements the measurement of intake airflow. The semiconductor chip 5 rectifies the amount of intake airflow, which is detected by using the sensor portion 4, and sends the rectified amount of intake airflow. The semiconductor chip 5 is molded in a primary molded resin.

The sensor portion 4 is inserted in the sub-bypass passage 2b to measure the amount of intake airflow in a thermal manner. In the example of FIG. 1, the sensor portion 4 has a chip configuration (circuit board configuration). It is noted that, the sensor portion 4 may be a bobbin type resistive element including a single resistor element.

The semiconductor chip 5 is configured to implement ND conversion on the output signal sent from the sensor portion 4. Specifically, the semiconductor chip 5 converts the output signal, which is an analog voltage signal, into a digital signal. Subsequently, the semiconductor chip 5 implements digital compensation on the converted digital signal. Subsequently, the semiconductor chip 5 further implements D/A conversion on the compensated signal. Subsequently, the semiconductor chip 5 sends the converted signal through a connector 2c to an engine control unit (ECU). The connector 2c is formed in the resin housing 2. The ECU is equipped in the vehicle at a position different from the position of the Airflow meter 1.

The semiconductor chip 5 includes an A/D converter 6, a digital processing unit 7, a D/A converter 8, an internal memory device 9, and an oscillator circuit 10. The A/D converter 6 digitizes the voltage detection signal (analog signal) of the sensor portion 4. The digital processing unit 7 adjusts the digitized detection signal originally sent from the sensor portion 4. That is, the digital processing unit 7 implements digital adjustment (digital processing) to adjust the digitized detection signal, which is before being adjusted. The D/A converter 8 implements analog conversion on the digital signal adjusted with the digital processing unit 7. Specifically, the D/A converter 8 implements frequency modulation on the signal, which is after being adjusted. The D/A converter 8 is an example of a frequency modulation unit. The internal memory device 9 is configured to store data for implementing the digital adjustment (digital processing). The internal memory device 9 is, for example, an EEPROM. The oscillator circuit 10 applies a reference signal (oscillating frequency) for operation of the A/D converter 6, the digital processing unit 7, and the D/A converter 8.

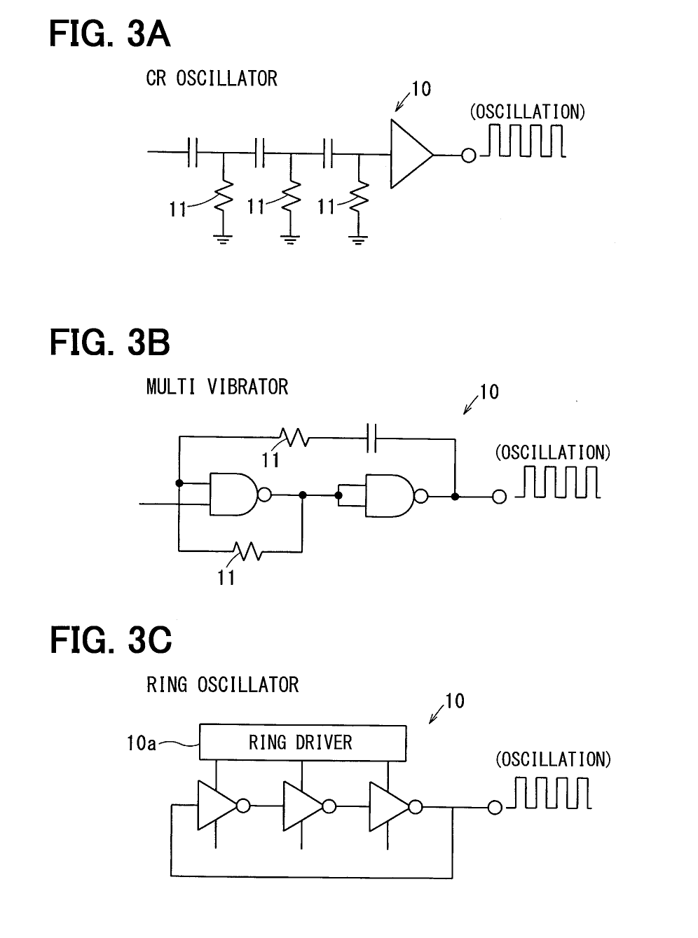

As described above, the oscillator circuit 10 is configured to apply the oscillating frequency as an operation reference on the A/D converter 6, the digital processing unit 7, and the D/A converter 8. The oscillator circuit 10 includes a resistor 11, which controls an oscillating frequency. The oscillator circuit 10, which includes the resistor 11 to control the oscillating frequency, may be an CR oscillator circuit shown in FIG. 3A, a multi-vibrator oscillator circuit shown in FIG. 3B, and/or a ring oscillator circuit shown in FIG. 3C. A ring driver circuit 10a shown in FIG. 3C includes a CR load. The CR load includes a circuit including the resistor 11, which controls the oscillating frequency.

According to the present embodiment, the resistor 11, which controls the oscillating frequency, is configured with a combination of a positive temperature coefficient resistor and a negative temperature coefficient resistor. The positive temperature coefficient resistor increases in resistance in response to increase in temperature. The negative temperature coefficient resistor decreases in resistance in response to increase in temperature.

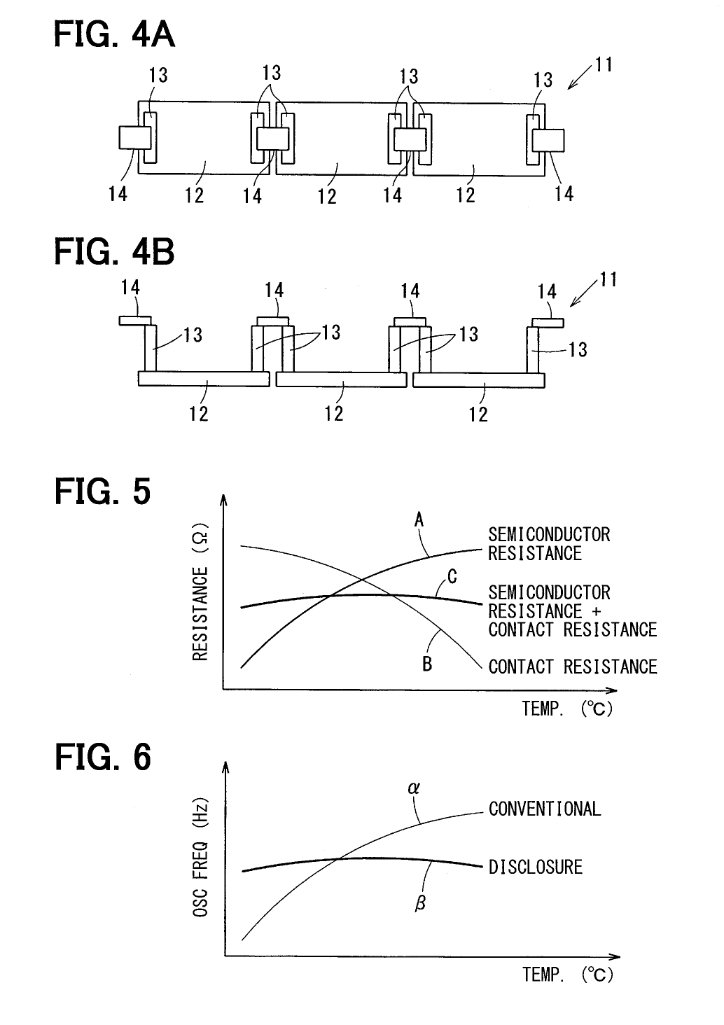

As described above, the oscillator circuit 10 is formed on the semiconductor chip 5. As shown in FIG. 3A to 4B, the resistor 11, which controls the oscillating frequency, is configured with combination of multiple semiconductor resistor elements 12 and multiple contact resistor elements 13. The multiple semiconductor resistor elements 12 are formed on the semiconductor chip 5. The multiple contact resistor elements 13 are independent from the multiple semiconductor resistor elements 12. That is, the multiple contact resistor elements 13 may be different objects separately equipped from the multiple semiconductor resistor elements 12. That is, the multiple contact resistor elements 13 may be distant from the multiple semiconductor resistor elements 12. In FIGS. 4A and 4B, an electric connector unit 14 is a wiring member configured with an electrically conductive material. The electric connector unit 14 electrically connects ends of the contact resistor elements 13, which are adjacent to each other.

The multiple semiconductor resistor elements 12 are an example of the positive temperature coefficient resistor. As shown by a solid line A in FIG. 5, the positive temperature coefficient resistor has a positive temperature coefficient and increases in resistance in response to increase in temperature. The multiple contact resistor elements 13 are an example of the negative temperature coefficient resistor. As shown by a solid line B in FIG. 5, the negative temperature coefficient resistor has a negative temperature coefficient and decreases in resistance in response to increase in temperature.

The resistor 11, which controls the oscillating frequency, is configured to control a number of usage of each of the semiconductor resistor elements 12 and the contact resistor elements 13 and a ratio of the number of usage of each of the semiconductor resistor elements 12 and the contact resistor elements 13. Therefore, as shown by a solid line C in FIG. 5, the resistor 11 has a characteristic to restrict a fluctuation in resistance even when a temperature varies. The resistor 11, which controls the oscillating frequency, may be optimized in the number of usage of each of the semiconductor resistor elements 12 and the contact resistor elements 13 and a ratio of the number of usage of each of the semiconductor resistor elements 12 and the contact resistor elements 13. Therefore, the resistor 11 substantially has a flat temperature characteristic.

FIGS. 3A to 3C show examples of the resistor 11 including the multiple semiconductor resistor elements 12 and the multiple contact resistor elements 13, which are in series connection. The configuration of the resistor 11 is not limited to the example of FIGS. 3A to 3C. The resistor 11 may include the multiple semiconductor resistor elements 12 and the multiple contact resistor elements 13, which are in parallel connection. Alternatively or in addition, the resistor 11 may include the multiple semiconductor resistor elements 12 and the multiple contact resistor elements 13, which are in combination of both series connection and parallel connection. In those ways, the resistor 11 may be substantially enabled to have a flat temperature characteristic.

(Operation Effect)

As described above, according to the embodiment, the oscillator circuit 10 includes the resistor 11, which controls the oscillating frequency. The resistor 11 includes combination of the semiconductor resistor elements 12, which have the positive temperature characteristics, and the contact resistor elements 13, which have the negative temperature characteristics. In this way, the resistor 11 is enabled to have a substantially flat temperature characteristic. As shown by a solid line 13 in FIG. 6, the present configuration enables to restrict fluctuation in the oscillating frequency, even when an environmental temperature of the oscillator circuit 10 changes.

Therefore, even when an environmental temperature of the oscillator circuit 10 changes, the temperature characteristic of the oscillator circuit 10 may be restricted from causing an error in an operation accuracy of A/D conversion and/or D/A conversion. That is, variation in a measurement result of the airflow meter 1 due to change in the environmental temperature of the oscillator circuit 10 can be restricted. Thus, the present configuration enables to enhance reliability in measurement of the airflow meter 1.

According to the above embodiments, the configuration of the present disclosure is employed in the oscillator circuit 10 of the airflow meter 1. It is noted that, the configuration of the present disclosure may be employed in the oscillator circuit 10 for a sensor device, which is configured to measure a physical quantity, other than the quantity of airflow, such as a pressure, an acceleration, a magnetic flux, and/or a humidity.

As described above, the oscillator circuit includes the resistor, which controls the oscillating frequency. The resistor is configured with the combination of the positive temperature coefficient resistor and the negative temperature coefficient resistor. The present configuration restricts variation in the resistance of the resistor, which controls the oscillating frequency, in response to change in the temperature. As a result, temperature dependency of the oscillating frequency of the oscillator circuit can be restricted.

It should be appreciated that while the processes of the embodiments of the present disclosure have been described herein as including a specific sequence of steps, further alternative embodiments including various other sequences of these steps and/or additional steps not disclosed herein are intended to be within the steps of the present disclosure.

While the present disclosure has been described with reference to preferred embodiments thereof, it is to be understood that the disclosure is not limited to the preferred embodiments and constructions. The present disclosure is intended to cover various modification and equivalent arrangements. In addition, while the various combinations and configurations, which are preferred, other combinations and configurations, including more, less or only a single element, are also within the spirit and scope of the present disclosure.

What is claimed is:

1. An oscillator circuit comprising:
a resistor configured to control an oscillating frequency, wherein
the resistor includes a positive temperature coefficient resistor and a negative temperature coefficient resistor, wherein
the positive temperature coefficient resistor has a resistance, which increases in response to increase in temperature, and
the negative temperature coefficient resistor has a resistance, which decreases in response to increase in temperature.

2. The oscillator circuit according to claim 1, wherein
the oscillator circuit is equipped on a semiconductor chip,
the positive temperature coefficient resistor includes a plurality of semiconductor resistor elements having a positive temperature coefficient,
the negative temperature coefficient resistor includes a plurality of contact resistor elements having a negative temperature coefficient,
the semiconductor resistor elements are located on the semiconductor chip, and
the contact resistor elements are independent from the semiconductor resistor element.

3. The oscillator circuit according to claim 2, wherein
the semiconductor chip is equipped to a sensor device, and
the sensor device is configured to implement A/D conversion on a sensor signal and subsequently to implement digital adjustment on the sensor signal and to output the sensor signal.

4. The oscillator circuit according to claim 3, wherein the sensor device is an airflow meter configured to measure an amount of intake airflow.
